(19) United States
(12) Patent Application Publication
(10) Pub. No.: US 2004/0201078 A1
(43) Pub. Date: Oct. 14, 2004

(54) Field plate structure for high voltage devices

(76) Inventor: Liping Ren, Los Angeles, CA (US)

Correspondence Address: OSTROLENK FABER GERB & SOFFEN, 1180 AVENUE OF THE AMERICAS, NEW YORK, NY, 100368403

(21) Appl. No.: 10/823,298

(22) Filed: Apr. 12, 2004

Related U.S. Application Data
(60) Provisional application No. 60/462,562, filed on Apr. 11, 2003.

(51) Int. Cl. H01L 23/58

(52) U.S. Cl. 257/500

(57) ABSTRACT

A semiconductor device which includes a field plate structure comprising a plurality of vertically arranged field plates.

### RELATED APPLICATION

This application is based on and claims benefit of U.S. Provisional Application No. 60/462,562, filed on Apr. 11, 2003, entitled Three Layer Field Plate Structure for 650V High Voltage Devices, to which a claim of priority is hereby made.

### BACKGROUND OF THE INVENTION

The breakdown voltage of a semiconductor device having a PN junction is limited by the breakdown voltage of the PN junction itself. The practical maximum breakdown voltage of a PN junction is actually lower than its theoretical breakdown voltage. The discrepancy between the actual and the theoretical breakdown voltage is in part due to strong electric fields at the periphery of the PN junction itself. At this periphery, there is a transition between the electric field within the semiconductor material and the electric field in the surrounding material such as the surrounding dielectric material.

To reduce the intensity of the electric field in high electric field regions in high voltage semiconductor devices passivation structures are typically used. The purpose of the passivation structure is to provide a transition between the high electric field area near the PN junction to an area of lower potential. A passivation structure essentially reduces the electric field intensity by spreading the field lines to reduce field crowding near the PN junction thereby reducing the electric field gradient.

A known passivation structure is a field plate. A conventional field plate is comprised essentially of a relatively thick field oxide which resides over the semiconductor die and a conductive layer residing over the field oxide.

Field plates are well known for use with lateral conduction MOSFETs in CMOS technology and for other semiconductor devices to reduce high electric field gradients at the surface of the semiconductor die.

The industrial demand for cost-effectiveness is causing the designers to design semiconductor devices with smaller features. Thus, for example, in lateral conduction MOSFETs, as the photolithography line width is decreased, the field oxide thickness also decreases. As a result, for example, in 0.35 micron CMOS technology, the initial breakdown voltage of high voltage (600 volts and higher) devices with conventional multiple floating field plate (“MFETP”) structures is decreased to below 600 volts because of the high electric field concentration on the oxides under the field plates. The decrease in the breakdown voltage is due to the reduction in the thickness of the field oxide.

It would be desirable to provide a field plate arrangement for lateral high voltage, low on resistance MOSFET devices with less sensitivity to surface charge.

It is further desirable to have a field plate arrangement which can be integrated into high voltage devices of over about 600 volts using 0.35 micron CMOS technology.

### SUMMARY OF THE INVENTION

A field plate structure according to the present invention includes a plurality of field plates arranged vertically adjacent to one another. Each field plate according to the present invention is disposed over a respective field insulation body which may be a field oxide.

In the preferred embodiment of the present invention, a lateral conduction MOSFET includes a drift region which is disposed between a source region and a drain region. A first field plate is arranged over and spaced from the drift region by a field insulation body which may be a field oxide. Disposed over the first field plate is a second field plate which is spaced from the first field plate by another field insulation body, which may also be a field oxide. The second field plate includes a first portion and a second portion which is spaced from the first portion by a gap. A device according to the preferred embodiment may further include a third field plate disposed over the second field plate and spaced from the same by another field insulation body which may be a field oxide. The field plate also includes a first portion and a second portion which is spaced from the first portion by a gap.

In one embodiment of the present invention the first field plate extends from the gate electrode.

A field plate according to the present invention reduces the surface charge on the field insulation beneath each plate to permit the devices to withstand 650 V or more when applied in, for example, 0.35 micron CMOS.

Other features and advantages of the present invention will become apparent from the following description of the invention which refers to the accompanying drawings.

### BRIEF DESCRIPTION OF THE DRAWINGS

FIG. 1 schematically shows a cross-sectional view along line 1-1 in FIG. 3 of a portion of a device according to the present invention viewed in the direction of the arrows.

FIG. 2 graphically shows the electric field distribution along the drift region of an example of a device according to the present invention.

FIG. 3 schematically shows a top plan view of a portion of a device according to the present invention.

### DETAILED DESCRIPTION OF THE DRAWINGS

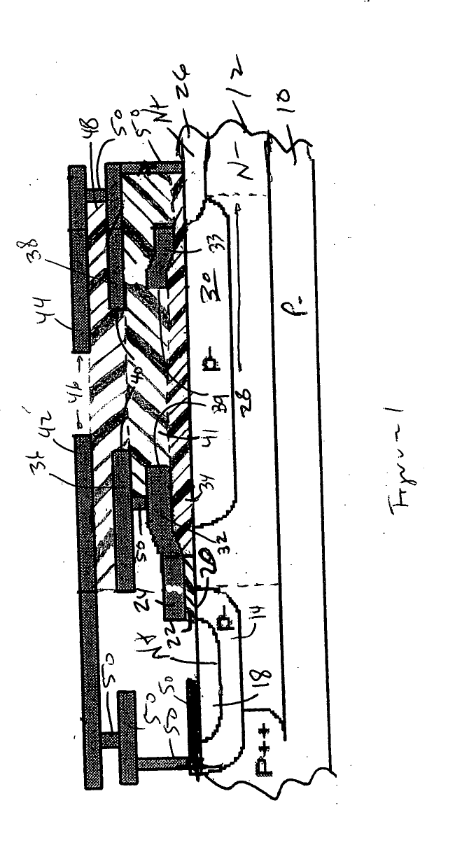

Referring to FIG. 1, an LDMOS according to the present invention includes semiconductor substrate 10 of a first conductivity which has formed over a major surface thereof an epitaxially formed semiconductor layer 12 of a second conductivity. In the preferred embodiment of the present invention, substrate 10 and epitaxially formed semiconductor layer 12 are comprised of silicon. Also, in the preferred embodiment of the present invention the first conductivity is P type, while the second conductivity is N type.

An LDMOS according to the present invention further includes body region 14. Body region 14 is formed in epitaxially formed semiconductor layer 12 and is of the first conductivity type. Source region 18 of the second conductivity type is formed and wholly contained within body region 14. Source region 18 is adjacent invertible channel region 20 in body region 14. Formed over invertible channel region 20 is a gate structure which includes gate insulation 22, and gate electrode 24. Gate insulation 22 is formed preferably from silicon dioxide and gate electrode 24 is preferably formed from conductive polysilicon.

An LDMOS according to the preferred embodiment of the present invention further includes drain region 26 which is of the second conductivity type and is formed in epitaxially formed semiconductor layer 12. Drain region 26 is spaced from body region 14 by drift region 28 in epitaxially formed semiconductor layer 12. An LDMOS according to the preferred embodiment further includes resurf region 30. Resurf region 30 is of the first conductivity type and is found in epitaxially formed semiconductor layer 12 between drain region 26 and body region 14 over at least a portion of drift region 28.

An LDMOS according to the preferred embodiment includes a field plate structure according to the present invention which is formed over resurf region 30. A field plate structure according to the present invention includes a first field plate having first portion 32 and second portion 33 spaced from its first portion 32 by gap 39. The first field plate is disposed over and spaced from resurf region 30 by first insulation layer 34. First portion 32 of the first field plate is preferably an extension of gate electrode 24 and is thus formed from the same material. Both first portion 32 and second portion 33 in the preferred embodiment are conductive polysilicon and gap 39 between them is about 60 microns wide. First insulation layer 34 is formed preferably from a field oxide and is preferably about 0.4 microns thick at its thickest section.

A field plate according to the present invention includes a second field plate having first portion 36 and second portion 38 spaced from its first portion 36 by gap 40. The second field plate is disposed over second field insulation 41 which is preferably composed of field oxide and is preferably 1.3 microns thick at its thickest section. Thus, the second field plate is disposed over a field insulation layer that is about 1.7 microns thick. In the preferred embodiment of the present invention gap 40 between first portion 36 of the second field plate and second portion 38 of the second field plate is about 45 microns wide.

A field plate structure according to the present invention further includes a third field plate. The third field plate includes first portion 42 and second portion 44 which is spaced from first portion 42 by gap 46. In the preferred embodiment gap 46 is about 25 microns wide. The third field plate is disposed over third field insulation layer 48. Third field insulation layer 48 is preferably 1.4 microns thick at its thickest section and composed of field oxide.

In the preferred embodiment of the present invention, second portion 44 of the third field plate is electrically connected to second portion 38 of the second field plate by an electrical connector 50. Second portion 38 of the second field plate is electrically connected to drain region 26 by an electrical connector 50. Second portion 33 of the first filed plate is electrically connected to second portion 39 of the second field plate by an electrical connector 50. Furthermore, first portion 36 of the second field plate is electrically connected to first field plate 32 by an electrical connector 50. In addition, first portion 42 of the third field plate is electrically connected to source region 20 and preferably to body region 14 by one electrical connector or a series of connectors 50.

A field plate structure according to the present invention was successfully incorporated in a 600V plus LDMOS power IC based on 0.35 micron CMOS technology. The device included a drift region of about 70 microns wide. The following were the parameters used:

| | |
|---|---|
| First field insulation 34 | 0.4 microns (at thickest section) |
| Second field insulation 41 | 1.3 microns (at thickest section) |
| Third field insulation 48 | 1.4 microns (at thickest section) |
| Second Field Plate | |
| First portion 36 | 1.5 microns (width over drift region) |
| Second portion 38 | 10 microns (width over drift region) |
| Gap 40 | 45 microns |
| Third Field Plate | |
| First portion 42 | 20 microns (width over drift region) |
| Second portion 44 | 25 microns (width over drift region) |
| Gap 46 | 25 microns |

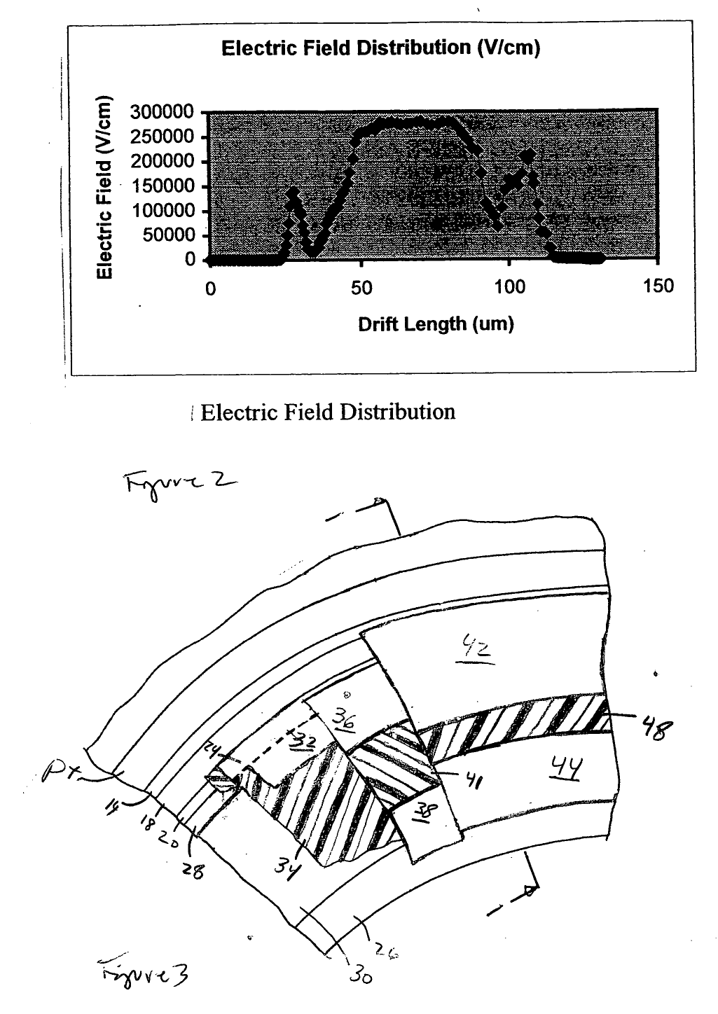

The device with the above parameters exhibited a breakdown voltage of about 650V. FIG. 2 shows the electric field distribution of the device in volts/cm along the length of the drift region.

Referring now to FIG. 3, the preferred embodiment of a device according to the present invention may be structured to include annular field plates, a portion of which is illustrated in FIG. 3. In such a structure drain region 26 is preferably surrounded by the field plates and other features described above. For example, drain region 26 would be disposed in the center and the remaining features would annularly surround drain region 26. The curved slope of the features shown in FIG. 3 is intended to illustrate the annularity of the features. The annular shape of the field plates and other features is preferably circular. Other annular shapes, however, can be adopted without deviating from the present invention.

Although the present invention has been described in relation to particular embodiments thereof, many other variations and modifications and other uses will become apparent to those skilled in the art. It is preferred, therefore, that the present invention be limited not by the specific disclosure herein.

1. A semiconductor device comprising:
a semiconductor substrate of a first conductivity;
an epitaxially formed semiconductor layer of a second conductivity formed over said substrate;
a body region of said first conductivity formed in said epitaxially formed semiconductor layer;
a source region of said second conductivity formed in said body region, said source region being adjacent an invertible channel in said body region;
a gate structure formed over said invertible channel region, said gate structure including a gate electrode which is spaced from said invertible channel by a gate insulation layer;
a drain region formed in said epitaxially formed semiconductor layer, said drain region and said body region being spaced from one another by a drift region in said epitaxially formed semiconductor layer; and
a field plate structure disposed over said drift region, said field plate structure including a first field plate disposed over a first insulation layer of a first thickness, a second field plate disposed over a second insulation layer of a second thickness, said second insulation layer being formed over said first insulation layer, and a third field plate spaced from said second field plate by a third insulation layer of a third thickness.

2. A semiconductor device according to claim 1, wherein said first insulation layer is comprised of an oxide.

3. A semiconductor device according to claim 1, wherein said first thickness is 0.4 microns.

4. A semiconductor device according to claim 1, wherein said second insulation layer is comprised of an oxide.

5. A semiconductor device according to claim 1, wherein said second thickness is 1.3 microns.

6. A semiconductor device according to claim 1, wherein said third insulation layer is comprised of an oxide.

7. A semiconductor device according to claim 1, wherein said third thickness is 1.4 microns.

8. A semiconductor device according to claim 1, wherein said first field plate extends from said gate electrode.

9. A semiconductor device according to claim 1, wherein said first field plate is comprised of conductive poly silicon.

10. A semiconductor device according to claim 1, wherein said second field plate is comprised of a first portion and a second portion, said first portion and said second portion being spaced from one another by a gap.

11. A semiconductor device according to claim 10, wherein said gap between said first portion of said second field plate and said second portion of said second field plate is 45 microns.

12. A semiconductor device according to claim 1, wherein said third field plate is comprised of a first portion and a second portion, said first and second portions being spaced from one another by a gap.

13. A semiconductor device according to claim 12, wherein said gap between said first portion of said third field plate and said second portion of said second field plate is 25 microns.

14. A semiconductor device according to claim 1, wherein said second field plate includes a first annular portion and a second annular portion, said annular portions being disposed around said drain region and spaced from one another by a gap.

15. A semiconductor device according to claim 14, wherein said gap between said first annular portion and said second annular portion of said second field plate is 45 microns.

16. A semiconductor device according to claim 1, wherein said third field plate includes a first annular portion and a second annular portion, said annular portions being disposed around said drain region and spaced from one another by a gap.

17. A semiconductor device according to claim 16, wherein said gap between said first annular portion and said second annular portion of said third field plate is 25 microns.

18. A semiconductor device according to claim 1, wherein said second field plate includes a first annular portion and a second annular portion, said annular portions being disposed around said drain region and spaced from one another by a first gap; said third field plate includes a first annular portion and a second annular portion, said annular portions being disposed around said drain region and spaced from one another by a second gap, said first gap being wider than said second gap.

19. A semiconductor device according to claim 18, wherein said first gap is about 45 microns and said second gap is about 25 microns.

20. A semiconductor device according to claim 18, wherein said first field plate terminates below said first portion of said second field plate.

21. A semiconductor device according to claim 18, wherein said second portion of said second field plate is electrically connected to said drain region, and to said second portion of said third field plate.

22. A semiconductor device according to claim 18, wherein said first portion of said second field plate is electrically connected to said first field plate.

23. A semiconductor device according to claim 18, wherein said first portion of said third field plate is electrically connected to said source region.

24. A semiconductor device according to claim 1, further comprising a resurf region of said first conductivity formed in said drift region below said field plate structure.

25. A field plate structure comprising:
a first field plate;
a second field plate disposed above and spaced from said first field plate; and
a third field plate disposed above and spaced from said second field plate.

26. A field plate structure according to claim 25, wherein said second field plate includes a first portion spaced from a second portion by a first gap, and said third field plate includes a first portion and a second portion spaced from said first portion by a second gap, said first gap being wider than said second gap.

27. A field plate structure according to claim 26, wherein said first portion and said second portion of each of said first and second field plates is annular.

28. A field plate structure according to claim 26, wherein said first portion of said second field plate is electrically connected to said first field plate and said second portion of said second field plate is electrically connected to said second portion of said third field plate.

29. A field plate structure according to claim 25, wherein said first field plate is insulated from said second field plate by an insulation layer and said second field plate is spaced from said third field plate by another insulation layer.
